(19) United States
(12) Patent Application Publication
(10) Pub. No.: US 2017/0110385 A1
(43) Pub. Date: Apr. 20, 2017

(54) HEAT-CONDUCTIVE SHEET AND PRODUCTION METHOD THEREFOR

(71) Applicant: Panasonic Intellectual Property Management Co., Ltd., Osaka (JP)

(72) Inventors: KEIJI KAWAJIRI, Hokkaido (JP); KAZUHIRO MIURA, Hokkaido (JP); MASAFUMI NAKAYAMA, Hokkaido (JP); HIROSHI EBINA, Hokkaido (JP); HIROFUMI YAMADA, Hokkaido (JP)

(21) Appl. No.: 15/128,927

(22) PCT Filed: Mar. 18, 2015
(86) PCT No.: PCT/JP2015/001503

§ 371 Date: Sep. 23, 2016

(30) Foreign Application Priority Data
Apr. 8, 2014 (JP) 2014-079121

(51) Int. Cl. H01L 23/373; B32B 9/04; B32B 7/14; H01L 21/48

(52) U.S. Cl. CPC H01L 23/3735; H01L 21/4871; B32B 9/04; B32B 7/14; B32B 2307/304

(57) ABSTRACT

A heat-conductive sheet includes a laminated sheet and first and insulating sheets bonded to first and second main surfaces of the laminated sheet. The laminated sheet includes graphite sheets and one or more adhesive layers disposed alternately on the graphite sheets to bonds the graphite sheets to each other. The first insulating sheet is bonded to the second insulating sheet outside an outer circumferential edge of the laminated sheet to seal the laminated sheet between the first and second insulating sheets. The laminated sheet includes an outer circumferential portion connected to the outer circumferential edge and an inner portion apart from the outer circumferential edge. The outer circumferential portion of the laminated sheet has a thickness smaller than a thickness of the inner portion. The heat-conductive sheet has high reliability of sealing the insulating sheet.

### TECHNICAL FIELD

The present invention relates to a heat-conductive sheet that has high thermal conductivity in a surface direction and a large amount of heat transport, and a method of manufacturing the heat-conductive sheet.

### BACKGROUND ART

In recent years, an operating speed of various electronic devices has been significantly improved, and increases an amount of heat generated from electronic components, such as semiconductor devices, accordingly. In order to operate electronic devices stably, a heat-conductive sheet, such as a graphite sheet, is used in these heat generating electronic components to diffuse and dissipate the heat. However, if graphite powders are partially desorbed from a graphite sheet, the graphite sheet may cause a short circuit due to conductivity of the graphite sheet. For this reason, to seal a graphite sheet, insulating sheets are bonded to both main surfaces of the graphite sheet, and the insulating sheets are bonded to each other outside an outer circumferential edge of the graphite sheet.

As an amount of heat generated from a heating element increases, a heat-conductive sheet is required to have a large amount of heat transport, in addition to a high thermal conductivity in a surface direction.

A conventional heat-conductive sheet similar to the above-mentioned heat-conductive sheet is disclosed in PTL 1.

### CITATION LIST

### Patent Literature

PTL 1: Japanese Patent Laid-Open Publication No. 2005-210035

### SUMMARY

A heat-conductive sheet includes a laminated sheet and first and insulating sheets bonded to first and second main surfaces of the laminated sheet. The laminated sheet includes graphite sheets and one or more adhesive layers disposed alternately on the graphite sheets to bonds the graphite sheets to each other. The first insulating sheet is bonded to the second insulating sheet outside an outer circumferential edge of the laminated sheet to seal the laminated sheet between the first and second insulating sheets. The laminated sheet includes an outer circumferential portion connected to the outer circumferential edge and an inner portion apart from the outer circumferential edge. The outer circumferential portion of the laminated sheet has a thickness smaller than a thickness of the inner portion.

The heat-conductive sheet has high reliability of sealing the insulating sheet.

### BRIEF DESCRIPTION OF DRAWINGS

FIG. 1A is a plan view of a heat-conductive sheet in accordance with an exemplary embodiment.

FIG. 1B is a cross-sectional view of the heat-conductive sheet along line 1B-1B shown in FIG. 1A.

FIG. 2A shows the heat-conductive sheet in accordance with the embodiment for illustrating a method of manufacturing the heat-conductive sheet.

FIG. 2B shows the heat-conductive sheet in accordance with the embodiment for illustrating the method of manufacturing the heat-conductive sheet.

FIG. 2C shows the heat-conductive sheet in accordance with the embodiment for illustrating the method of manufacturing the heat-conductive sheet.

FIG. 2D shows the heat-conductive sheet in accordance with the embodiment for illustrating the method of manufacturing the heat-conductive sheet.

FIG. 3 is a cross-sectional view of a comparative example of a heat-conductive sheet.

### DETAIL DESCRIPTION OF PREFERRED EMBODIMENT

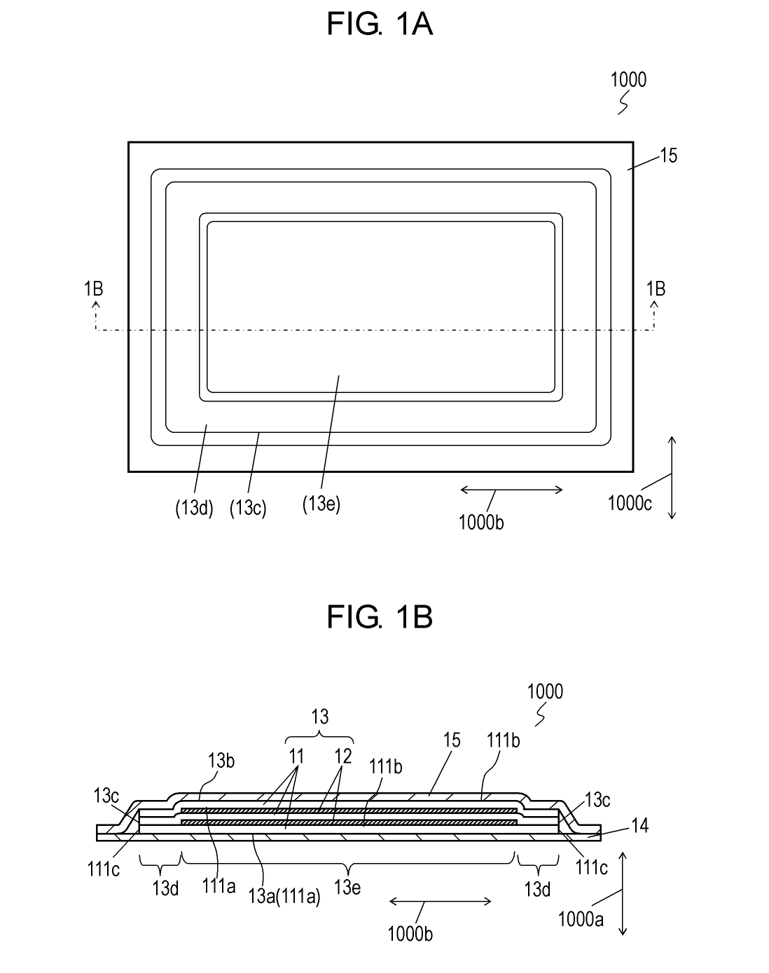

FIG. 1A is a plan view of heat-conductive sheet 1000 in accordance with an exemplary embodiment. FIG. 1B is a cross-sectional view of heat-conductive sheet 1000 along line 1B-1B shown in FIG. 1A. Three graphite sheets 11 are bonded with adhesive layers 12 to form laminated sheet 13. Laminated sheet 13 is placed between insulating sheets 14 and 15 to seal heat-conductive sheet 1000.

Graphite sheet 11 is made of a pyrolytic graphite sheet with a thickness of about 10 μm. The heat conductivity of graphite sheet 11 in a surface direction is about 1950 W/m° K. Adhesive layer 12 is made of styrene butadiene rubber, has a thickness of about 3 μm, and can be bonded by heat pressing. Graphite sheets 11 are bonded with adhesive layers 12 to constitute laminated sheet 13. Insulating sheets 14 and 15 are films made of polyethylene terephthalate and have thicknesses of about 10 μm. Acrylic pressure sensitive adhesives are disposed on surfaces of insulating sheets 14 and 15 facing laminated sheet 13. Laminated sheet 13 is bonded to insulating sheets 14 and 15 with the adhesives while insulating sheet 14 is bonded to insulating sheet 15 with the adhesives to seal laminated sheet 13 between insulating sheets 14 and 15.

Adhesive layer 12 is disposed in an area inside apart from an outer circumferential edge of graphite sheet 11 by about 1 mm. Thus, an outer circumferential portion of laminated sheet 13 including the outer circumferential edge of the laminated sheet 13 is thinner than an inner portion of laminated sheet 13 by only the thickness of adhesive layer 12. Herein, the inner portion of laminated sheet 13 is apart from the outer circumferential edge of laminated sheet 13 and located inside the outer circumferential portion of laminated sheet 13. When laminated sheet 13 is placed between insulating sheets 14 and 15 to seal laminated sheet 13, the outer circumferential portion of the laminated sheet 13 has a thickness thinner than that of the inner portion located inside the outer circumferential portion. Thus, insulating sheet 14 and insulating sheet 15 are easily in contact with each other outside the outer circumferential edge of the laminated sheet 13, thereby improving reliability of sealing.

According to the embodiment, the adhesives are formed on only surfaces of insulating sheets 14 and sheet 15 facing laminated sheet 13, but either or both of insulating sheets 14 and 15 may be made of a double-sided adhesive tape. This configuration allows heat-conductive sheet 1000 to be easily bonded to, e.g. a heating element or a housing.

In heat-conductive sheet 1000, laminated sheet 13 includes plural graphite sheets 11 and one or more adhesive layers 12 which are arranged alternately on graphite sheets 11 and bond graphite sheets 11. Laminated sheet 13 has main surface 13a, main surface 13b opposite to main surface 13a, and outer circumferential edge 13c which are connected to main surfaces 13a and 13b and which surrounds main surfaces 13a and 13b. Insulating sheet 14 is bonded to main surface 13a of laminated sheet 13. Insulating sheet 15 is bonded to main surface 13b of laminated sheet 13. Laminated sheet 13 is sealed with insulating sheets 14 and 15 bonded to each other outside outer circumferential edge 13c of laminated sheet 13. Laminated sheet 13 has outer circumferential portion 13d that is connected to outer circumferential edge 13c, and inner portion 13e that is apart from outer circumferential edge 13c. Outer circumferential portion 13d of laminated sheet 13 has a thickness smaller than that of inner portion 13e. In laminated sheet 13, inner portion 13e is located inside outer circumferential portion 13d.

Outer circumferential edge 13c of laminated sheet 13 entirely surrounds main surfaces 13a and 13b.

Graphite sheet 11 has main surface 111a, main surface 111b opposite to main surface 111a, and outer circumferential edge 111c which that is connected to main surfaces 111a and 111b and which entirely surrounds main surfaces 111a and 111b. One or more adhesive layers 12 may be apart from outer circumferential edge 111c of graphite sheet 11. One outermost graphite sheet out of graphite sheets 11 stacked in laminating direction 1000a has main surface 111a constituting main surface 13a of laminated sheet 13 while the other outermost graphite sheet out of graphite sheets 11 has main surface 111b constituting main surface 13b of laminated sheet 13. Main surface 111b of one graphite sheet 11 is bonded to main surface 111a of graphite sheet 11 with adhesive layer 12.

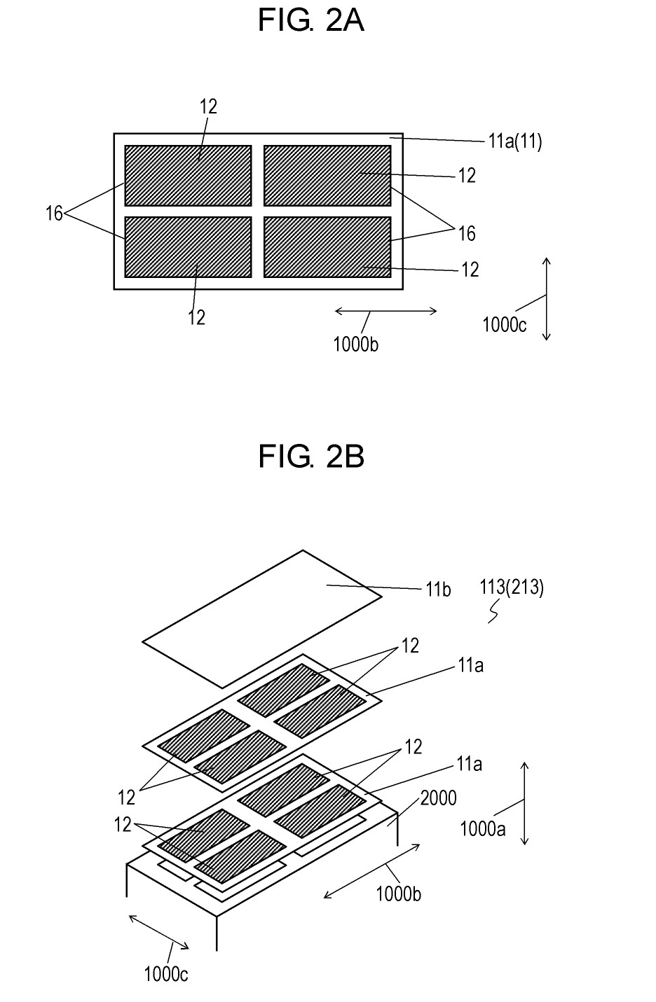

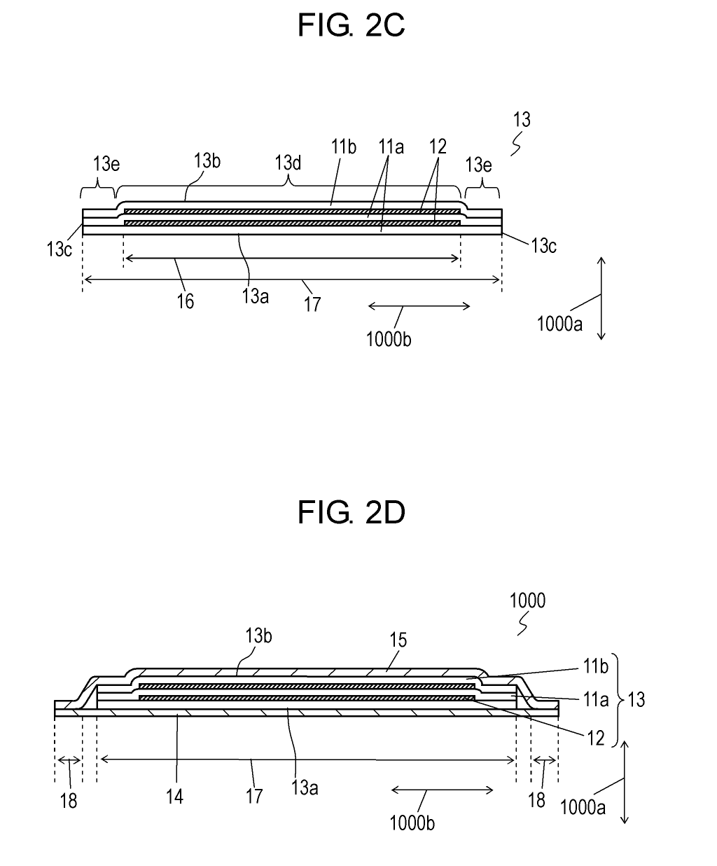

A method of manufacturing heat-conductive sheet 1000 in accordance with the embodiment will be described with reference to drawings. FIGS. 2A to 2D show heat-conductive sheet 1000 in accordance with the embodiment for illustrating the method of manufacturing heat-conductive sheet 1000.

First, as shown in FIG. 2A, adhesive layers 12 are formed on areas 16 of large-sized graphite sheets 11a. Graphite sheet 11a is made of a pyrolytic graphite sheet with a thickness of about 10 μm, and has a size of about 500 mm by 250 mm in a surface direction of the sheet. In accordance with the embodiment, adhesive layer 12 has a rectangular shape with a size of about 100 mm by 200 mm. Four adhesive layers 12 are formed on areas 16 each constituting respective one of graphite sheets 11a. Adhesive layer 12 is formed by adding a solvent made of butyl acetate to an adhesive agent made of styrene butadiene rubber to make a liquid whose viscosity is reduced, and then, patterning applying the liquid on graphite sheet 11a. The liquid can be patterned with a mask. The applying may be performed by, e.g. spraying or printing. In order to form thin adhesive layer 12, spraying is desirable. Graphite sheet 11a having adhesive layers 12 provided thereon is inserted into a dryer at a temperature of about 100° C. to evaporate the solvent. After the solvent is evaporated, adhesive layer 12 has a thickness of about 3 μm.

Next, as shown in FIG. 2B, a predetermined number of graphite sheets 11a are aligned and stacked on one another in laminating direction 1000a, and then, graphite sheet 11b having no adhesive layer thereon is further stacked on the stacked sheets to obtain large-sized laminated sheet 113. Graphite sheet 11b is made of a pyrolytic graphite sheet with a thickness of about 10 μm. In the case that a total of two graphite sheets are stacked, graphite sheet 11b is just stacked on graphite sheet 11a.

Next, laminated sheet 113 including graphite sheets 11a and 11b stacked on one another is heat-pressed with an iron that is heated at about 150° C., thereby bonding graphite sheet 11a and graphite sheet 11b in areas 16. A graphite sheet has excellent thermal conductivity in surface directions 1000b and 1000c perpendicular to laminating direction 1000a, i.e., parallel to main surfaces 13a and 13b (main surfaces of graphite sheets 11a and 11b) of laminated sheet 13. This configuration allows heat to transmit uniformly, so that graphite sheets 11a and 11b can be bonded uniformly.

Next, as shown in FIG. 2C, large-sized laminated sheet 113 including graphite sheets 11a and 11b bonded to one another is punched with metallic mold 2000 to allow the laminated sheet to have area 17, and is cut at outer circumferential edge 13c, thereby providing laminated sheet 13. Area 17 extends outward from area 16 by about 2 mm. If a portion having an adhesive, such as an adhesive layer or a double-sided adhesive tape, exists between graphite sheets 11a and 11b , graphite sheets 11a and 11b can be hardly punched accurately since an adhesive agent thereof adheres to metallic mold 2000 when graphite sheets 11a and 11b are punched with metallic mold 2000. In contrast, according to the embodiment, no adhesive layer exists at outer circumferential edge 13c of laminated sheet 13 which is a portion to be punched with metallic mold 2000, so that graphite sheets 11a and 11b can be punched accurately. Besides, since adhesive layer 12 exists between graphite sheets 11a and 11b, area 16 is thicker than the periphery of area 17.

Next, laminated sheet 13 is stacked on insulating sheet 14. Then, insulating sheet 15 is stacked on laminated sheet 13 so as to sandwich laminated sheet 13 with insulating sheet 14. Subsequently, the stacked sheets are pressed with a roller to bond insulating sheet 14, laminated sheet 13, and insulating sheet 15, thereby providing laminated sheet 213. In laminated sheet 213, laminated sheet 13 is positioned in area 17. Laminated sheet 213 is punched with a metallic mold in area 18 which expands outward from laminated sheet 13 (area 17) by about 1 mm, thereby providing heat-conductive sheet 1000 shown in FIG. 2D.

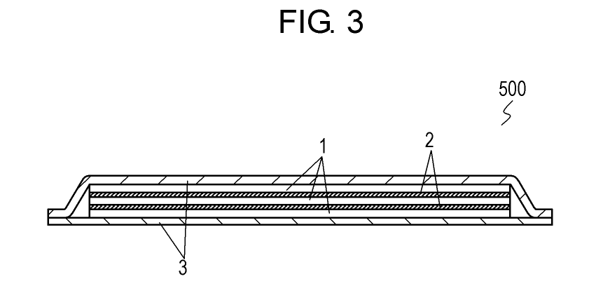

FIG. 3 is a cross-sectional view of a comparative example of heat-conductive sheet 500. A pyrolytic graphite sheet has a very high thermal conductivity in a surface direction of the sheet. The thermal conductivity increase as its thickness decreases. On the other hand, an amount of heat transport decreases as the thickness decreases. Heat-conductive sheet 500 shown in FIG. 3 includes plural pyrolytic graphite sheets 1 bonded with double-sided adhesive tape 2, and insulating sheet 3 bonded to both main surfaces of pyrolytic graphite sheet 1. Pyrolytic graphite sheets 1 are bonded to one another with double-sided adhesive tape 2, and are cut. Then, insulating sheets 3 are bonded to both the main surfaces, thereby providing heat-conductive sheet 500. The pyrolytic graphite sheets which are bonded to one another can be hardly cut. If an insulating sheet seals outside an edge surface of the thick pyrolytic graphite sheet, reliability of the sealing may not be secured.

In heat-conductive sheet 1000 according to the embodiments shown in FIGS. 1A, 1B, and 2D, insulating sheet 14 and insulating sheet 15 are films made of polyethylene terephthalate with a thickness of about 10 μm, and acrylic pressure sensitive adhesives are provided on their surfaces facing laminated sheet 13. The pressure sensitive adhesives bond laminated sheet 13 to insulating sheets 14 and 15. Insulating sheet 14 is bonded to insulating sheet 15 around laminated sheet 13 to seal laminated sheet 13 between insulating sheets 14 and 15. In area 16, adhesive layer 12 exists between graphite sheets 11a and 11b, but no adhesive layer exists around area 16. Therefore, a circumferential portion of area 17 has a thickness smaller than that of area 16. When insulating sheets 14 and 15 are bonded by applying pressure with a roller, the roller contacts directly above area 17 and directly above area 18, thereby pressurizing a seal part, which is formed by area 18, greatly and sufficiently. Thus, insulating sheet 14 can be easily bonded to insulating sheet 15 around laminated sheet 13, thereby improving the reliability of sealing.

As mentioned above, heat-conductive sheet 1000 can be manufactured by the following method. One or more adhesive layers 12 are formed in one or more areas 16 of one or more graphite sheets 11a. Graphite sheet 11b is placed on one or more graphite sheets 11a in laminating direction 1000a with one or more adhesive layers 12 stacked on one or more graphite sheets 11a alternately. One or more graphite sheets 11a and graphite sheet 11b are bonded with one or more adhesive layers 12. One or more graphite sheets 11a and graphite sheet 11b are to allow laminated sheet 13 to have area 17. Insulating sheet 14 is placed on insulating sheet 15 while laminated sheet 13 is disposed between insulating sheets 14 and 15. Then, insulating sheet 14 is bonded to insulating sheet 15 in area 18, so that insulating sheets 14 and 15 are directly bonded in area 18, thereby providing heat-conductive sheet 1000. Viewing in laminating direction 1000a, one or more areas 16 are located inside area 17. Viewing in laminating direction 1000a, area 17 is located inside area 18.

One or more graphite sheets 11a and graphite sheet 11b may be bonded by heat pressing.

Areas 16 may be apart from outer circumferential edge 11c surrounding graphite sheet 11a.

One or more graphite sheets 11a and graphite sheet 11b may be punched in area 17 to obtain laminated sheet 13.

### INDUSTRIAL APPLICABILITY

A heat-conductive sheet according to the present invention has high thermal conductivity in a surface direction and a large amount of heat transport, and is useful for heat dissipation of heating components.

### REFERENCE MARKS IN THE DRAWINGS

11 graphite sheet (first graphite sheet, second graphite sheet)
11a graphite sheet (first graphite sheet)
11b graphite sheet (second graphite sheet)
111c outer circumferential edge
12 adhesive layer
13 laminated sheet
13a main surface (first main surface)
13b main surface (second main surface)
13c outer circumferential edge
13d outer circumferential portion
13e inner portion
14 insulating sheet (first insulating sheet)
15 insulating sheet (second insulating sheet)
16 area (first area)
17 area (second area)
18 area (third area)
1000 heat-conductive sheet
1000a laminating direction

1. A heat-conductive sheet comprising:
a laminated sheet including a plurality of graphite sheets and one or more adhesive layers disposed alternately on the plurality of graphite sheets to bonds the plurality of graphite sheets to each other, the laminated sheet having a first main surface, a second main surface opposite to the first main surface, and an outer circumferential edge connected to the first main surface and the second main surface and surrounding the first main surface and the second main surface;
a first insulating sheet bonded to the first main surface of the laminated sheet; and
a second insulating sheet bonded to the second main surface of the laminated sheet,
wherein the first insulating sheet is bonded to the second insulating sheet outside the outer circumferential edge of the laminated sheet to seal the laminated sheet between the first insulating sheet and the second insulating sheet,
wherein the laminated sheet includes an outer circumferential portion connected to the outer circumferential edge and an inner portion apart from the outer circumferential edge, and
wherein the outer circumferential portion of the laminated sheet has a thickness smaller than a thickness of the inner portion of the laminated sheet.

2. The heat-conductive sheet according to claim 1, wherein the one or more adhesive layers are apart from outer circumferential edges of the plurality of graphite sheets.

3. The heat-conductive sheet according to claim 1, wherein the first insulating sheet comprises a double-sided adhesive tape.

4. A method of manufacturing a heat-conductive sheet, comprising:
forming one or more adhesive layers on respective one or more first areas of one or more first graphite sheets;
placing a second graphite sheet on the one or more first graphite sheets in a laminating direction while the one or more adhesive layers are placed alternately on the one or more first graphite sheets the second graphite sheet;
bonding the one or more first graphite sheets to the second graphite sheet via the one or more adhesive layers;
providing a laminated sheet by cutting the one or more first graphite sheets and the second graphite sheet to allow the laminated sheet to have a second area; and
providing a heat-conductive sheet by placing a first insulating sheet on a second insulating sheet while the laminated sheet is placed between the first insulating sheet and the second insulating sheet, and bonding the first insulating sheet, the laminated sheet, and the second insulating sheet at a third area of the laminated sheet,
wherein, viewing in the laminating direction, the one or more first areas are located inside the second area, and
wherein, viewing in the laminating direction, the second area is located inside the third area.

5. The method according to claim 4,
wherein said forming the one or more adhesive layers on the respective one or more first areas of the one or more first graphite sheets comprises forming a plurality of adhesive layers on a plurality of first areas of a plurality of first graphite sheets,
wherein said placing the second graphite sheet on the one or more first graphite sheets in the laminating direction while the one or more adhesive layers are placed alternately on the one or more first graphite sheets the second graphite sheet comprises placing the second graphite sheet on a plurality of first graphite sheets in the laminating direction while a plurality of adhesive layers are placed alternately on the plurality of first graphite sheets the second graphite sheet,
wherein said bonding the one or more first graphite sheets to the second graphite sheet via the one or more adhesive layers comprises bonding the plurality of first graphite sheets to the second graphite sheet via the one or more adhesive layers, and
wherein said providing the laminated sheet by cutting the one or more first graphite sheets and the second graphite sheet comprises providing the laminated sheet by cutting the plurality of first graphite sheets and the second graphite sheet at the second area.

6. The method according to claim 4, wherein said bonding the one or more first graphite sheets to the second graphite sheet via the one or more adhesive layers comprises bonding the one or more first graphite sheets to the second graphite sheet via the one or more adhesive layers by heat pressing.

7. The method according to claim 4, wherein the one or more first areas are apart from an outer circumferential edge of the one or more first graphite sheets surrounding the one or more first graphite sheets, respectively.

8. The method according to claim 4, wherein said providing the laminated sheet by cutting the one or more first graphite sheets and the second graphite sheet to allow the laminated sheet to have the second area comprises providing the laminated sheet by punching the second area of the one or more first graphite sheets and the second graphite sheet.
